(19) United States
(12) Patent Application Publication
(10) Pub. No.: US 2013/0161523 A1
(43) Pub. Date: Jun. 27, 2013

(54) RADIATION DETECTOR WITH VOLTAGE-BIASED FOCUS GRID

(71) Applicants: John Eric Tkaczyk, Delanson, NY (US); Vladimir A. Lobastov, Clifton Park, NY (US); Yanfeng Du, Rexford, NY (US)

(72) Inventors: John Eric Tkaczyk, Delanson, NY (US); Vladimir A. Lobastov, Clifton Park, NY (US); Yanfeng Du, Rexford, NY (US)

(73) Assignee: General Electric Company, Schenectady, NY (US)

(21) Appl. No.: 13/336,389

(22) Filed: Dec. 23, 2011

(51) Int. Cl. G01T 1/24; H01L 31/18; G01T 1/16

(52) U.S. Cl. 250/370.13; 250/394; 250/370.12; 438/73; 257/E31.124

(57) ABSTRACT

A radiation detector is provided employing a focus grid electrode. The focus grid electrode is biased relative to one or more anode electrodes. In this manner, movement of electrons to the anode electrodes may be enhanced, such as due to a higher electrical field strength in a conversion material and/or due to focusing of the resulting electrical field on the anode electrodes.

### BACKGROUND

Non-invasive imaging technologies allow images of the internal structures of a subject (e.g., a patient or object) to be obtained without performing an invasive procedure on the patient or object. Non-invasive imaging systems may operate based on the transmission and detection of radiation through or from a subject of interest (e.g., a patient or article of manufacture). For example, X-ray based imaging techniques (such as mammography, fluoroscopy, computed tomography (CT), and so forth) typically utilize an external source of X-ray radiation that transmits X-rays through a subject and a detector disposed opposite the X-ray source that detects the X-rays transmitted through the subject. Other radiation based imaging approaches, such as positron emission tomography (PET) or single photon emission computed tomography (SPECT) may utilize a radiopharmaceutical that is administered to a patient and which results in the emission of gamma rays from locations within the patient's body. The emitted gamma rays are then detected and the gamma ray emissions localized.

Thus, in such radiation-based imaging approaches, the radiation detector is an integral part of the imaging process and allows the acquisition of the data used to generate the images of interest. In certain radiation detection schemes, the radiation may be detected by use of a scintillating material that converts the higher energy gamma ray or X-ray radiation to optical light photons (e.g., visible light), which can then be detected by photodetector devices, such as photodiodes. In other detection schemes, the X-ray or gamma ray energy may be directly converted to electrical signals in the detector apparatus, and these electrical signals are read-out electronically. Such direct conversion detectors generally have a construction of a semiconductor layer with charge-collecting electrodes on either side of the layer. The voltage bias applied to the electrodes causes one electrode to be the anode collecting negatively charged electrons and the other electrode to be the cathode collecting positively-charged holes.

In certain of these direct conversion radiation detectors, the radiation passes through an electrode, such as an anode electrode, packaging prior to reaching the sensor component of the detector. Such a detector configuration may be described as being “anode illuminated” due to the radiation being initially incident on the anode side of the detector structure. In some circumstances, the signal observed at the anode may be smaller than in configurations where the radiation initially passes through the cathode material to interact with the sensor material (i.e., “cathode illuminated” configurations). However, anode illumination, though providing reduced signal at the anode contact, may still be desirable due to the shortened path traveled by the charge and the corresponding stability. Therefore, it may be desirable to have an anode illuminated detector configuration but also a high signal induction at the anode contacts of a radiation detector.

### BRIEF DESCRIPTION

In accordance with one embodiment, a radiation detector is provided. The radiation detector comprises a direct conversion material having a first surface and a second surface. A cathode electrode is positioned proximate to the first surface of the direct conversion material. A plurality of anode electrodes are positioned proximate to the second surface of the direct conversion material. The radiation detector also comprises a focus grid electrode positioned on the X-ray incident side and comprising a plurality of openings. Each opening surrounds a respective anode electrode within a plane.

In accordance with one embodiment, an imaging system is provided. The imaging system comprises a direct conversion radiation detector. The radiation detector comprises a direct conversion material having a first surface and a second surface. The radiation detector also comprises a cathode electrode positioned proximate to the first surface of the direct conversion material and a plurality of anode electrodes positioned proximate to the second surface of the direct conversion material. The radiation detector also comprises a focus grid electrode comprising a plurality of openings. Each opening surrounds a respective anode electrode within a plane. The imaging system further includes a data acquisition system in communication with the radiation detector and a controller controlling operation of the data acquisition system.

A method for forming a radiation detector is also provided. In accordance with one embodiment of the method, a cathode electrode is provided on a first surface of a direct conversion material. A plurality of anode electrodes are provided on a second surface of the direct conversion material. A focus grid electrode is provided on the second surface. The focus grid electrode comprises a plurality of openings and is positioned so that each opening surrounds a respective anode electrode within a plane.

### BRIEF DESCRIPTION OF THE DRAWINGS

These and other features and aspects of embodiments of the present invention will become better understood when the following detailed description is read with reference to the accompanying drawings in which like characters represent like parts throughout the drawings, wherein:

FIG. 1 is a block diagram illustrating an embodiment of a general imaging system that may incorporate a focus grid, in accordance with an aspect of the present disclosure;

FIG. 2 is a block diagram illustrating an embodiment of an X-ray imaging system that may incorporate a focus grid, in accordance with an aspect of the present disclosure;

FIG. 3 is a block diagram illustrating an embodiment of a positron emission tomography or single photon emission computed tomography (PET/SPECT) imaging system that may incorporate a focus grid, in accordance with an aspect of the present disclosure;

FIG. 4 depicts cross-sectional view of a conventional detector panel with electrical field lines;

FIG. 5 depicts a plan view of a portion of a detector panel in accordance with an aspect of the present disclosure;

FIG. 6 depicts a side-view of a portion of a detector panel in accordance with an aspect of the present disclosure; and

FIG. 7 depicts cross-sectional view of a detector panel with electrical field lines in accordance with an aspect of the present disclosure.

### DETAILED DESCRIPTION

The present disclosure relates to the use of direct conversion detectors, such as photon counting detectors, in radiation-based imaging applications, such as computed tomography (CT), positron emission tomography (PET), or single photon emission computed tomography (SPECT). In a direct conversion detector, each radiation photon that is absorbed in the conversion material (such as semi-conductor crystals) generates electrons and holes in proportion to the energy of the radiation photon. A voltage applied across the thickness of the sensor drives the electrons to the anode and the holes to the cathode. Because the mobility of the electrons is typically greater than the holes in semiconductors with good radiation stopping power, the electron charge is collected on an array of anode electrodes. The electron charge is converted by read-out circuit to a digital imaging signal. The holes are collected on a cathode that is common to the whole sensor area and are not typically converted to an imaging signal in conventional approaches. The anode pixel receiving the electrons is spatially correlated to the arrival position of each photon. Typically, the anode electrode is the pixel-array electrode and the cathode contact is the common electrode. However, the opposite arrangement, that is a pixel cathode, may be appropriate for other semiconductors where the hole signal is collected on an array of pixel cathodes and radiation incident to the cathode face.

In certain embodiments, the direct conversion detector is anode-illuminated (i.e., the X-rays or gamma rays passes through an anode-bearing surface of the detector before reaching the radiation conversion material). By illuminating the anode surface, the radiation is typically absorbed closer to the anode electrode and the electron signal is more readily collected. However, a consequence of this configuration may also be that a reduced signal is seen at the respective anodes due to depth-of-interaction effects as well as due to the electrons migrating to more than one anode (i.e., sharing of the observed charge between anode electrodes) or between anodes such that signal is lost. As discussed in the present disclosure, a focus grid may be employed that acts to focus or bias the electrons to respective anode electrodes. In this manner, the focus grid may act to reduce charge loss at the anodes.

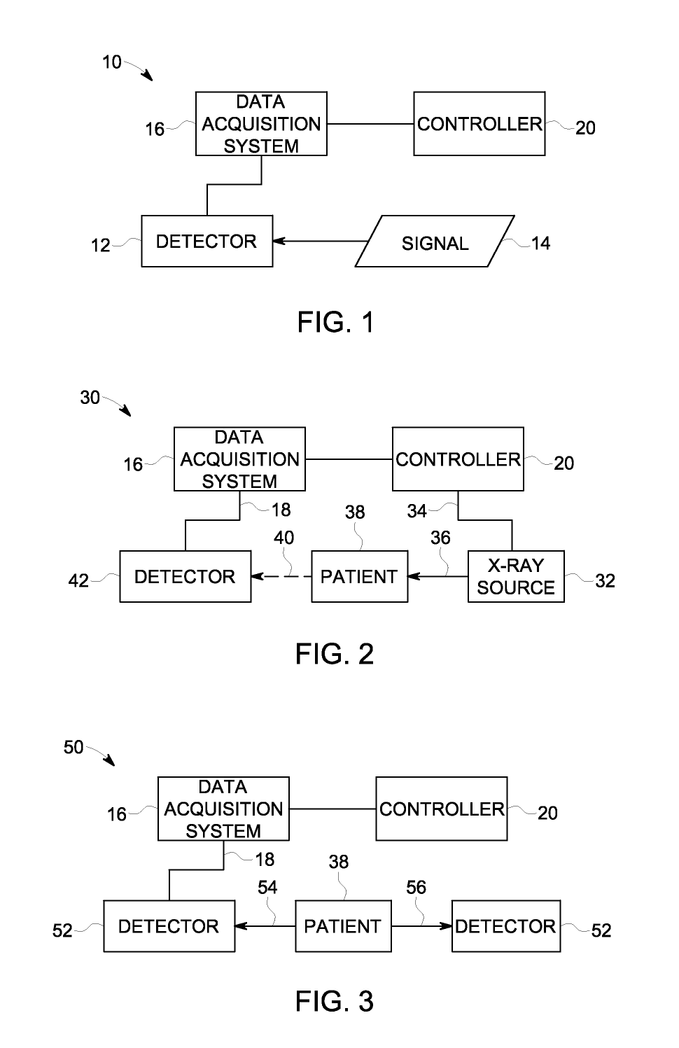

It should be noted that the present approaches may be utilized in a variety of imaging contexts, such as in medical imaging, product inspection for quality control, and for security inspection, to name a few. However, for simplicity, examples discussed herein relate generally to medical imaging, particularly radiation-based imaging techniques, such as: computed tomography (CT), mammography, tomosynthesis, C-arm angiography, conventional X-ray radiography, fluoroscopy, positron emission tomography (PET), and single-photon emission computed tomography (SPECT). However, it should be appreciated that these examples are merely illustrative and may be discussed merely to simplify explanation and to provide context for examples discussed herein. That is, the present approaches may be used in conjunction with any of the disclosed imaging technologies as well other suitable radiation-based approaches and in contexts other than medical imaging. Specifically, FIGS. 1-3 discuss embodiments of medical imaging systems that may utilize anode-illuminated direct conversion sensor packages, as discussed herein, with FIG. 1 being directed towards a general imaging system, FIG. 2 being directed towards an X-ray imaging system such as a CT/C-arm imaging system, and FIG. 3 being directed towards a PET or SPECT imaging system.

With the foregoing in mind, FIG. 1 provides a block diagram illustration of a generalized imaging system 10. The imaging system 10 includes a detector 12 for detecting a signal 14, such as emitted gamma rays or transmitted X-rays. The detector 12 may be a direct conversion type detector which directly generates electrical signals in response to incident radiation, i.e., without an intermediate conversion step by which the radiation is converted to another, lower-energy form, such as optical wavelengths. Generally, the more detection elements per unit of area in the detector 12, the greater its ability to spatially resolve such radiation, leading to higher quality images. In one embodiment, the signal 14 may pass through an anode electrode before reaching the radiation sensing material (i.e., direct conversion material) of the detector 12.

The detector 12 generates electrical signals in response to the detected radiation, and these electrical signals are sent through their respective channels to a data acquisition system (DAS) 16. Once the DAS 16 acquires the electrical signals, which may be analog signals, the DAS 16 may digitize or otherwise condition the data for easier processing. For example, the DAS 16 may filter the image data based on time (e.g., in a time series imaging routine), may filter the image data for noise or other image aberrations, and so on. The DAS 16 then provides the data to a controller 20 to which it is operatively connected. The controller 20 may be an application-specific or general purpose computer with appropriately configured software. The controller 20 may include computer circuitry configured to execute algorithms such as imaging protocols, data processing, diagnostic evaluation, and so forth. As an example, the controller 20 may direct the DAS 16 to perform image acquisition at certain times, to filter certain types of data, and the like. Additionally, the controller 20 may include features for interfacing with an operator, such as an Ethernet connection, an Internet connection, a wireless transceiver, a keyboard, a mouse, a trackball, a display, and so on.

Keeping such an approach in mind, FIG. 2 is a block diagram illustrating an embodiment of an X-ray imaging system 30 that may employ various features in accordance with the approaches noted above. The X-ray imaging system 30 may be an inspection system, such as for quality control, package screening, and safety screening, or may be a medical imaging system. In the illustrated embodiment, system 30 is an X-ray medical imaging system such as a CT or C-arm imaging system. In regards to the configuration of system 30, it may be similar in design to the generalized imaging system 10 described with respect to FIG. 1. For example, the system 30 includes the controller 20 operatively connected to the DAS 16, which allows the controlled acquisition of image data via an X-ray detecting array 42. In system 30, to enable the collection of image data, the controller 20 is also operatively connected to a source of X-rays 32, which may include one or more X-ray tubes.

The controller 20 may furnish a variety of control signals, such as timing signals, imaging sequences, and so forth to the X-ray source 32 via a control link 34. In some embodiments, the control link 34 may also furnish power, such as electrical power, to the X-ray source 32 via control link 34. Generally, the controller 20 will send a series of signals to the X-ray source 32 to begin the emission of X-rays 36, which are directed towards a subject of interest, such as a patient 38. The controller may also modify aspects of the operation of the detector and synchronize acquisition of signals at the detector with the X-ray source operation. Various features within the patient 38, such as tissues, bone, etc., will attenuate the incident X-rays 36. The attenuated X-rays 40, having passed through the patient 38, then strike the X-ray detecting array 42 to produce electrical signals representative of a corresponding data scan (i.e., an image). The X-ray detecting array 42 may be pixilated and formed from discrete detector elements such that hundreds or thousands of discrete detecting elements may be present on the X-ray detecting array 42. Each detecting element may correspond a single channel for data transmission.

In some imaging contexts, it can be important to transfer information that may be acquired substantially simultaneously, so as to correlate one acquired signal with another. One such imaging context is PET imaging systems, an embodiment of which is illustrated in FIG. 3. Specifically, FIG. 3 illustrates a block diagram of an embodiment of a PET imaging system 50 having a data link between a gamma ray detector array 52 and the DAS 16. In PET imaging, the detector 52 is generally configured to surround the patient 38. Specifically, the detector 52 of the PET system 50 may include a number of detector modules arranged in one or more rings about the imaging volume. For simplicity, the illustrated embodiment depicts two areas of the detector 52 disposed approximately 180 degrees apart so as to substantially simultaneously capture pairs of gamma rays that are emitted during imaging, as discussed below. It should be noted that in other embodiments, such as in SPECT embodiments, the detector 52 may be disposed as a ring, but a single, collimated photon is detected rather than a coincident photon pair as in PET.

The detector 52 detects photons generated from within the patient 38 by a decaying radionuclide. For example, a radionuclide may be injected into the patient 38 and may be selectively absorbed by certain tissues (e.g., tissues having abnormal characteristics such as a tumor). As the radionuclide decays, positrons are emitted. The positrons may collide with complementary electrons (e.g., from atoms within the tissue), which results in an annihilation event. The annihilation event, in PET, results in the emission of a first and second gamma photon 54, 56. The first and second gamma photons 54, 56 may strike the detectors 52 at separate areas approximately 180 degrees from one another. Typically, the first and second gamma photons 54, 56 strike the detectors 52 at approximately the same time (i.e., are coincident), and are correlated with one another. The origin of the annihilation event may then be localized. This is repeated for many annihilation events, which generally results in an image in which the contrast of the abnormal tissues appear enhanced. In this regard, it should be noted that the detector 52 may advantageously include a plurality of discrete detecting elements (e.g., pixilated elements) so as to allow high spatial resolution to produce an image of sufficient quality. For example, by detecting a number of gamma ray pairs, and calculating the corresponding lines traveled by these pairs, the concentration of the radioactive tracer in different parts of the body may be estimated and a tumor, thereby, may be detected. Therefore, accurate detection and localization of the gamma rays forms a fundamental and foremost objective of the PET system 50.

As noted above with respect to the generalized system of FIG. 1, in certain embodiments the X-ray detecting array 42 of the system of FIG. 2 or the gamma ray detector 52 of the system of FIG. 3 may be configured so as to be anode-illuminated in which an anode electrode is disposed on a surface of the detector facing the source of emission of the X-rays (FIG. 2) or gamma rays (FIG. 3). In accordance with aspects of the present disclosure, the X-ray detecting array 42 or gamma ray detector 52 (generalized as detector 12) may be constructed so as to include structured anodes used in conjunctions with focus grids, as discussed herein, to improve the observed or measured signal at each anode.

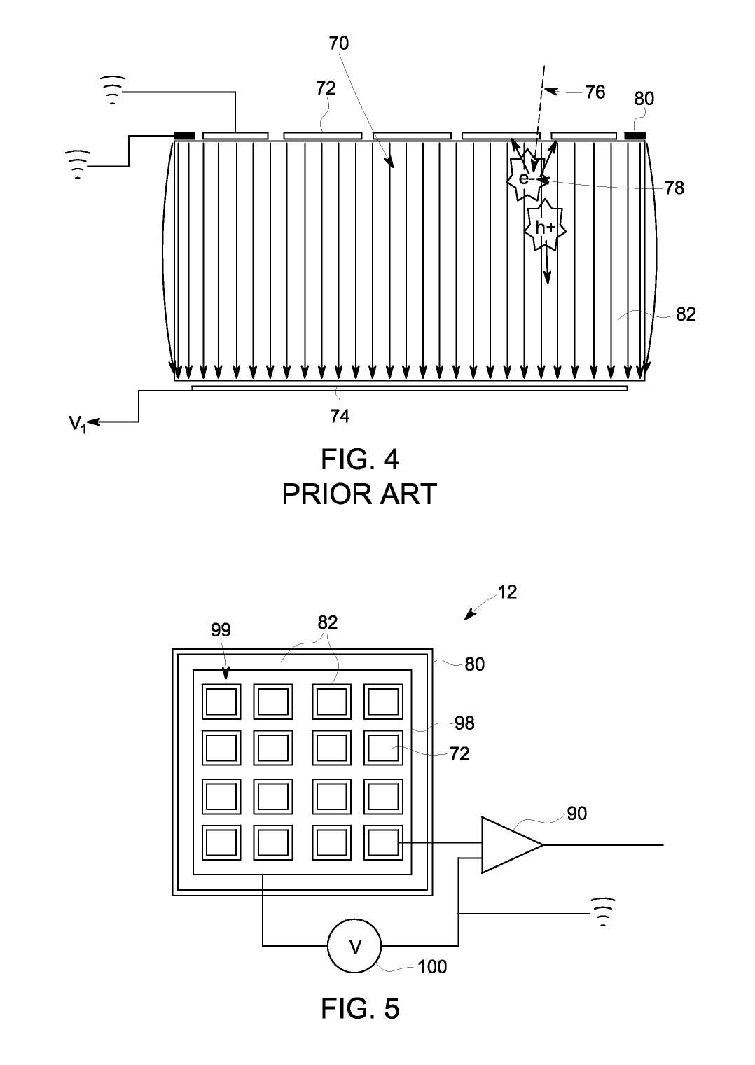

To facilitate explanation, and turning to FIG. 4, a conventional implementation of a detector panel that does not include a focus grid is depicted in cross section. In this example, the detector panel includes anode electrodes (i.e., pixel electrodes) 72 on a surface facing the source of radiation 76 (e.g., X-rays or gamma rays). A guard ring 80 is also present and both the guard ring 80 and the anode electrodes 72 are connected to ground. Also present in the conventional detector is a common cathode electrode 74 held at a common voltage V₁ (e.g., between −500 V to −2,000 V, such as −1,000 V). When in use, a uniform electric field, denoted by field lines 70, is present. In the depicted example, when radiation 76 is absorbed (denoted at site 78) by a sensor material (i.e., direct conversion material 82) disposed between the anodes 72 and cathode 74, this interaction creates electrons (e) and holes (10. Depending on the implementation, the direct conversion material 82 may be based on cadmium telluride (CdTe), cadmium zinc telluride (CZT or CdZnTe), or any other suitable direct conversion radiation sensing material (such as gallium arsenide, mercury iodine, and so forth).

The electrons migrate toward the anode electrodes 72 while the holes (h⁺) migrate toward the common cathode 74. The electrons move faster and may be the only species measured in the timescale of the shaper circuit when the electric field is uniform, as shown in FIG. 4. That is, in such an implementation, the holes are not recorded. This electron-hole asymmetry creates a signal dependence on the depth-of-interaction such that radiation interaction events occurring closer to the anode 72 yield a smaller signal than events absorbed deeper into the direct conversion material 82.

Furthermore, in the conventional detector implementation depicted in FIG. 4, because the electric field 70 is relatively uniform in the direct conversion material 82, the electrons may drift to multiple pixels (i.e., anode electrodes 72) and create a smaller signal on any one anode 72. This charge sharing effect creates an error in the photon counting number and the energy spectrum measurement. Therefore, in a conventional anode-illuminated implementation, issues may arise related to one or both of depth-of-interaction signal dependence and charge sharing.

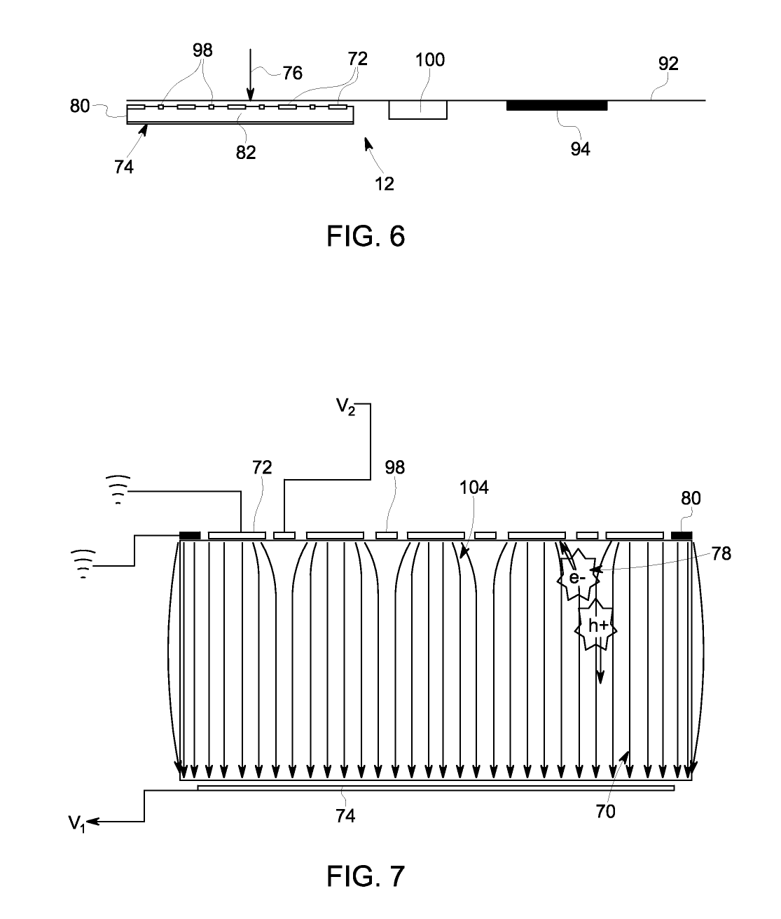

Turning to FIGS. 5 and 6, an implementation of a detector 12 in accordance with a present disclosure is depicted. In accordance with the depicted embodiment, a detector 12 or portion of such a detector 12 may include a plurality of anode electrodes 72 and a common cathode electrode 74 disposed on opposing faces of a non-conducting direct conversion material 82. The cathode electrode 74 can be voltage biased from −500 V to −2,000 V relative to the integrator input, discussed below. A metalized guard ring 80 may also be present to reduce or eliminate leakage current through the side wall. Typically the guard ring 80 is at ground potential (i.e., anode potential).

In the depicted embodiment, the each anode electrode 74 is in communication with an integrator 90, one of which is depicted for reference. The charge signal received at the integrator 90 is representative of incident X-ray energy. In one implementation, the integrator 90 is an integrator charge-to-voltage transimpedance amplifier, such as may be used in a photon counting circuit. The detector package may also include various structural features used in the readout of the detector elements, such as a flex or ridged circuit interconnect structure 92 or circuit board used to connect the various data collection structures and functionalities of the detector panel. For example, the interconnect structure 92 may connect the anode electrodes 72 with a downstream application-specific integrated circuit (ASIC), such as a readout ASIC 94, which may include features such as the integrators 90 or other signal readout and/or amplification structures.

In addition, a focus grid electrode 98 or contact is present. The focus grid electrode 98 is used to change the electric field profile in the conversion material 82, and to thereby improve the signal strength observed at the anode electrodes 72. In the depicted implementation, the focus grid electrode 98 is co-planar (i.e., in the same plane) with the anode electrodes 72 and is comprised of a plurality of holes or openings 99 within which respective anode electrodes 72 are positioned such that each anode electrode 72 is surrounded by (within the respective common plane), but not conductively connected to, the focus grid electrode 98. That is, the focus grid electrode 98 surrounds each anode electrode 72 but is not conductively connected to the respective anode electrodes 72. In this manner, a separate bias may be applied to the focus grid electrode 98 with respect to the anode electrodes 72.

In particular, in one implementation the focus grid electrode 98 is in communication with a bias circuit 100 that allows the focus grid electrode to be biased, in one implementation, between about −50 V to about +50 V. Thus, in operation, the focus grid electrode 98 may be biased so as to exhibit a voltage differential (e.g., −50 V to +50 V) relative to the surrounded anode electrodes 72. As discussed below, the focus grid electrode 98 allows modulation of the effective active collection area associated with the respective anode electrodes 72. In addition, the focusing effect provide by the focus grid electrode 98 provides for stronger electric fields about each anode electrode 72, and thereby provides for faster, more abrupt collection of electron charge pulses over time, thus allowing smaller anode electrodes 72 to be used if desired relative to system in which a focus grid electrode 98 is not employed. In one implementation employing a focus grid electrode 98, the pulse width is less than 10 nanoseconds.

By way of example, and turning to FIG. 7, shows how the voltage bias applied to the focus grid electrode 98 causes the electric field 70 to be focused (denoted at arrow 104) on each surrounded anode electrode 72 and to have higher strength in the vicinity of the anode electrodes 72. For example, when the focus grid electrode 98 is biased at a negative voltage V₂ (e.g., −20 V, −50 V, and so forth) the electric field 70 is more focused toward the anode electrodes 72. One result of higher field strength is that both electrons and hole drift more quickly. The electron signal rise time is faster and one can count at higher incident photon rates without pulse-pile-up. The holes move faster and can also be recorded within the timescale of the measurement circuit. Therefore, the charge induction signal within the integrator 90 will be acquired more quickly and the “peaking time” for the anode assembly with a negative bias at the focus grid electrode 98 will be shorter.

Further, as noted above, the electrical focusing effect causes field lines 70 to bend (arrow 104) and avoid the region between pixels (i.e., anode electrodes 72). In addition, the focus grid electrode 98, when employed, has the effect of screening the electric field of the charge cloud itself so that there is less charge sharing between anode electrodes 72. As a result, the main signal (called the weighting potential) is collected primarily on one anode electrode 72 and is more uniform as a function of depth-of-interaction.

These effects of employing a focus grid electrode 98 may be useful anode illuminated configurations because the incident radiation is more likely to be absorbed in the direct conversion material near the anode electrodes 72.

Technical effects of the invention include the formation and use of anode-illuminated direct conversion radiation detectors. In one embodiment, the radiation detectors include a focus gird electrode that can be biased relative to the anode electrodes present on the detector. Use of the focus grid electrode allow, among other things, generation of a stronger electric field in the direct conversion material, thus speeding the movement of electrons and holes within the material, and focusing of the electric field lines on the anode electrodes so that electrons within the direct conversion material are drawn toward the anode electrodes.

This written description uses examples to disclose the present subject matter, including the best mode, and also to enable any person skilled in the art to practice the disclosed approach, including making and using any devices or systems and performing any incorporated methods. It should also be understood that the various examples disclosed herein may have features that can be combined with those of other examples or embodiments disclosed herein. That is, the present examples are presented in such as way as to simplify explanation but may also be combined one with another. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A radiation detector, comprising:
a direct conversion material having a first surface and a second surface;
a cathode electrode positioned proximate to the first surface of the direct conversion material;
a plurality of anode electrodes positioned proximate to the second surface of the direct conversion material; and
a focus grid electrode positioned on the X-ray incident side and comprising a plurality of openings, wherein each opening surrounds a respective anode electrode within a plane.

2. The radiation detector of claim 1, comprising a bias circuit connected to the focus grid electrode, wherein the bias circuit is capable of applying a differential bias to the focus grid electrode relative to the anode electrodes.

3. The radiation detector of claim 1, wherein the direct conversion material comprises one or more of cadmium telluride (CdTe), cadmium zinc telluride (CZT or CdZnTe), gallium arsenide, or mercury iodine.

4. The radiation detector of claim 1, comprising a guard ring disposed about a portion of the radiation detector and configured to reduce or eliminate leakage current.

5. The radiation detector of claim 1, wherein the focus grid electrode, when differentially biased relative to the plurality of anode electrodes, alters the electric field profile between the plurality of anode electrodes and the cathode electrode.

6. The radiation detector of claim 1, wherein the focus grid electrode, when negatively biased relative to the plurality of anode electrodes, focuses the electric field on the anode electrodes.

7. The radiation detector of claim 1, wherein the cathode electrode is configured to be biased to between about −500 V to about −2,000 V.

8. The radiation detector of claim 1, wherein the focus grid electrode is configured to be biased between about −50 V to about +50 V relative to the plurality of anode electrodes.

9. The radiation detector of claim 1, wherein the focus grid electrode, when differentially biased relative to the plurality of anode electrodes, strengthens the electric field around each electrode.

10. An imaging system, comprising:
a direct conversion radiation detector, the radiation detector comprising:
a direct conversion material having a first surface and a second surface;
a cathode electrode positioned proximate to the first surface of the direct conversion material;
a plurality of anode electrodes positioned proximate to the second surface of the direct conversion material; and
a focus grid electrode comprising a plurality of openings, wherein each opening surrounds a respective anode electrode within a plane;
a data acquisition system in communication with the radiation detector; and
a controller controlling operation of the data acquisition system.

11. The imaging system of claim 10, comprising a bias circuit connected to the focus grid electrode, wherein the bias circuit is capable of applying a differential bias to the focus grid electrode relative to the anode electrodes.

12. The imaging system of claim 10, comprising one or more integrator circuits configured to accumulate charge of one or more of the anode electrodes.

13. The imaging system of claim 10, wherein the focus grid electrode, when differentially biased relative to the plurality of anode electrodes, alters the electric field profile between the plurality of anode electrodes and the cathode electrode.

14. The imaging system of claim 10, wherein the focus grid electrode, when negatively biased relative to the plurality of anode electrodes, focuses the electric field on the anode electrodes.

15. The imaging system of claim 10, wherein the focus grid electrode is configured to be biased between about −50 V to about +50 V relative to the plurality of anode electrodes.

16. The imaging system of claim 10, wherein the focus grid electrode, when differentially biased relative to the plurality of anode electrodes, strengthens the electric field around each electrode.

17. A method for forming a radiation detector, comprising:
providing a cathode electrode on a first surface of a direct conversion material;
providing a plurality of anode electrodes on a second surface of the direct conversion material;
providing a focus grid electrode on the second surface, wherein the focus grid electrode comprises a plurality of openings and the focus grid electrode is positioned so that each opening surrounds a respective anode electrode within a plane.

18. The method of claim 1, comprising connecting the focus grid electrode to a bias circuit configured to bias the focus grid electrode relative to the plurality of anode electrodes.

19. The method of claim 1, comprising connecting at least the anode electrodes to an interconnect structure capable of transmitting signals from the anode electrodes to one or more signal acquisition circuits.

20. The method of claim 1, comprising connecting the anode electrodes to one or more integrator circuits.
